(19) United States
(12) Patent Application Publication
(10) Pub. No.: US 2025/0022879 A1
(43) Pub. Date: Jan. 16, 2025

(54) Volume-Less Dipole Incorporation into CFET Having Common Gate

(71) Applicant: Taiwan Semiconductor Manufacturing Co., Ltd., Hsinchu (TW)

(72) Inventors: Yen-Jui Chiu, Hsinchu (TW); Te-Yang Lai, Hsinchu (TW); An Lee, Taipei City (TW); Jyun-Yi Wu, Hsinchu (TW); Shu-Han Chen, Hsinchu (TW); Da-Yuan Lee, Jhubei City (TW); Chi On Chui, Hsinchu (TW)

(21) Appl. No.: 18/351,099

(22) Filed: Jul. 12, 2023

(51) Int. Cl. H01L 27/092; H01L 21/822; H01L 21/8238; H01L 29/06; H01L 29/423; H01L 29/51; H01L 29/66; H01L 29/775

(52) U.S. Cl. CPC H01L 27/0922; H01L 21/8221; H01L 21/823807; H01L 21/823857; H01L 29/0673; H01L 29/42392; H01L 29/516; H01L 29/66439; H01L 29/66545; H01L 29/66553; H01L 29/775

(57) ABSTRACT

A method includes forming a first semiconductor channel region and a second semiconductor channel region, with the second semiconductor channel region overlapping the first semiconductor channel region, forming a first gate dielectric on the first semiconductor channel region, and forming a second gate dielectric on the second semiconductor channel region. A dipole dopant is incorporated into a first one of the first gate dielectric and the second gate dielectric to a higher atomic percentage, and a second one of the first gate dielectric and the second gate dielectric has a lower atomic percentage of the dipole dopant. A gate electrode is formed on both of the first gate dielectric and the second gate dielectric. The gate electrode and the first gate dielectric form parts of a first transistor, and the gate electrode and the second gate dielectric form parts of a second transistor.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 11 are views of intermediate stages in the manufacturing of CFETs in accordance with some embodiments.

FIGS. 12-1 through 12-7 illustrate the views of ex-situ dipole dopant doping in the formation of gate stacks of CFETs in accordance with some embodiments.

FIGS. 13-1 through 13-6 illustrate the views of in-situ dipole dopant doping in the formation of gate stacks of CFETs in accordance with some embodiments.

FIGS. 14-1 through 14-6 illustrate the views of ex-situ dipole dopant doping in the formation of gate stacks of CFETs in accordance with some embodiments.

FIGS. 15-1 through 15-6 illustrate the views of in-situ dipole dopant doping in the formation of gate stacks of CFETs in accordance with some embodiments.

FIG. 16 illustrates the schematic dipole dopant atomic percentages in the gate dielectric of a FET in accordance with some embodiments.

FIG. 17 illustrates a flow chart for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. Throughout the description, the terms “FET” and “transistor” are used interchangeably. In accordance with some embodiments, A CFET structure includes an NFET and a PFET, which share a common metal gate (with a common work function material). When the common metal gate has a p-type work function layer, an n-type dipole dopant is doped into the high-k dielectric layer of the NFET. When the common metal gate has an n-type work function layer, a p-type dipole dopant is doped into the high-k dielectric layer of the PFET. While Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFETs.

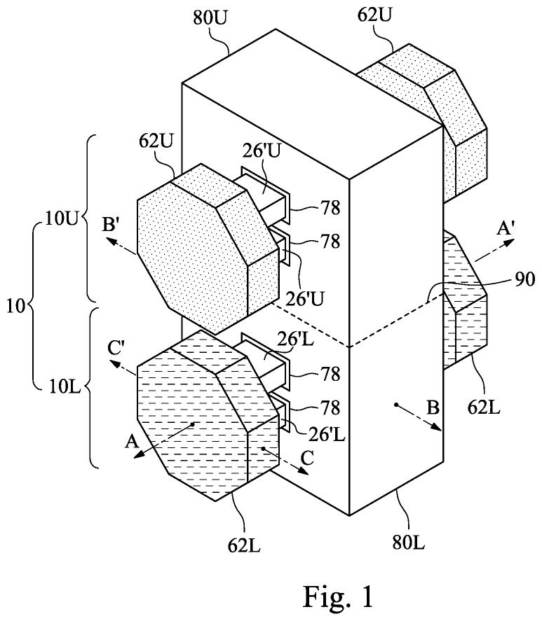

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Cross-section C-C′ is a vertical cross-section that is parallel to cross-section B-B′ and extends through the source/drain regions 62 of the CFETs. Subsequent figures may refer to these reference cross-sections for clarity.

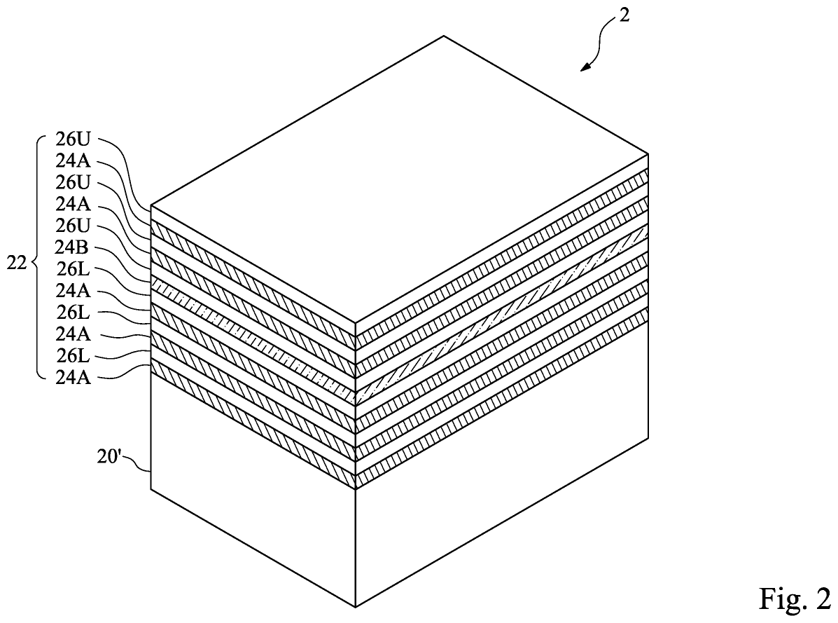

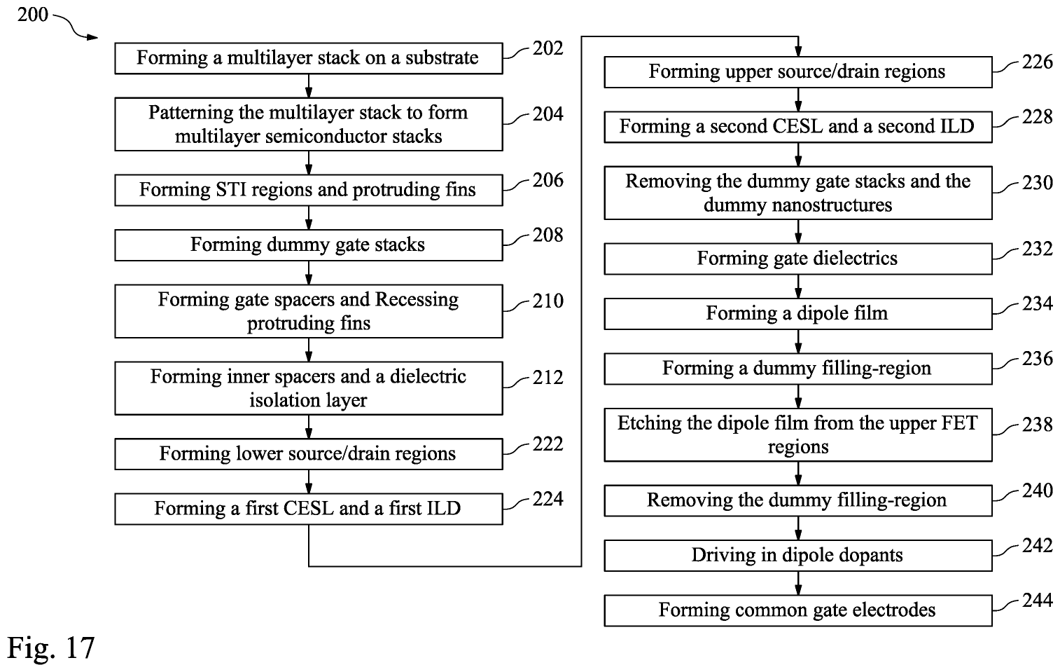

FIGS. 2 through 11 illustrate the cross-sectional views of intermediate stages in the formation of CFETs (as schematically represented in FIG. 1) in accordance with some embodiments. The corresponding processes are also reflected schematically in the process flow 200 as shown in FIG. 17. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1. The figures having digits followed by letter “C” illustrate the vertical cross-sectional views along a similar cross-section as the vertical reference cross-section C-C′ in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The respective process is illustrated as process 202 in the process flow 200 as shown in FIG. 17. The multi-layer stack 22 includes alternating dummy semiconductor layers 24 (including dummy semiconductor layers 24A and a dummy semiconductor layer 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

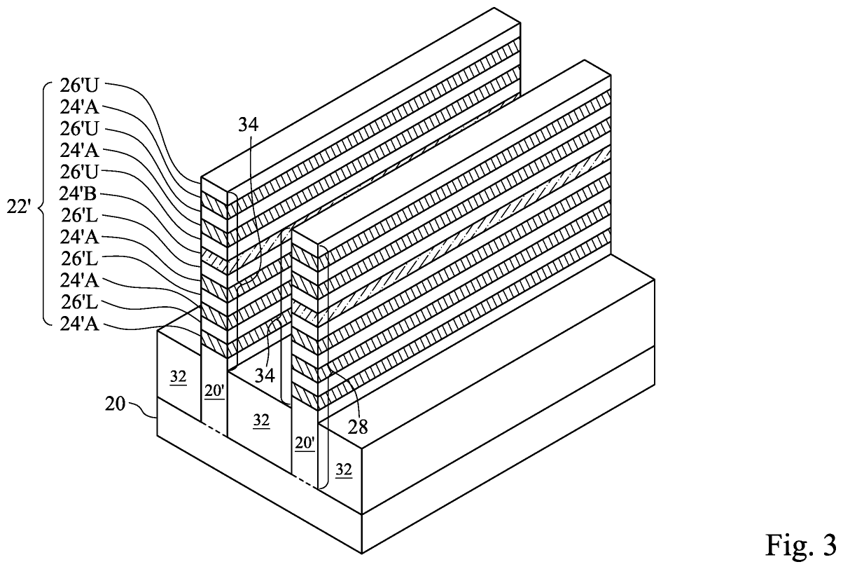

In FIG. 3, multi-layer stack 22 and substrate 20 are patterned to form semiconductor strips 28. The respective process is illustrated as process 204 in the process flow 200 as shown in FIG. 17. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “′” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process.

Isolation regions 32 are formed over the substrate 20 and between adjacent semiconductor strips 28. The respective process is illustrated as process 206 in the process flow 200 as shown in FIG. 17. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the isolation regions 32 include silicon oxide formed by an FCVD process, followed by an anneal process.

Isolation regions 32 are then recessed. The respective process is also illustrated as process 206 in the process flow 200 as shown in FIG. 17. Some upper portions of semiconductor strips 28 (including multi-layer stacks 22′) protrude higher than the remaining isolation regions 32 to form protruding fins 34.

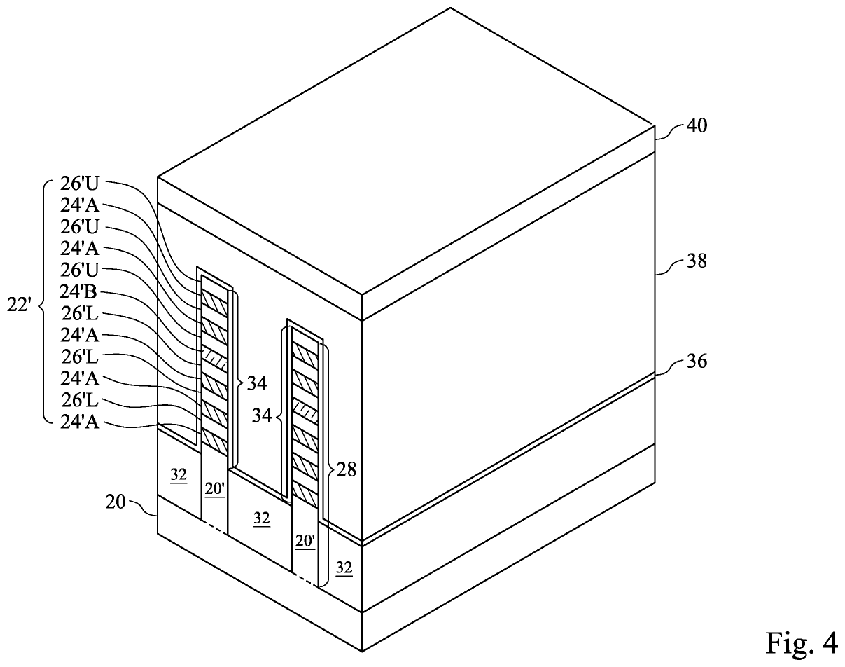

In FIG. 4, dummy dielectric layer 36 is formed on the protruding fins 34. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

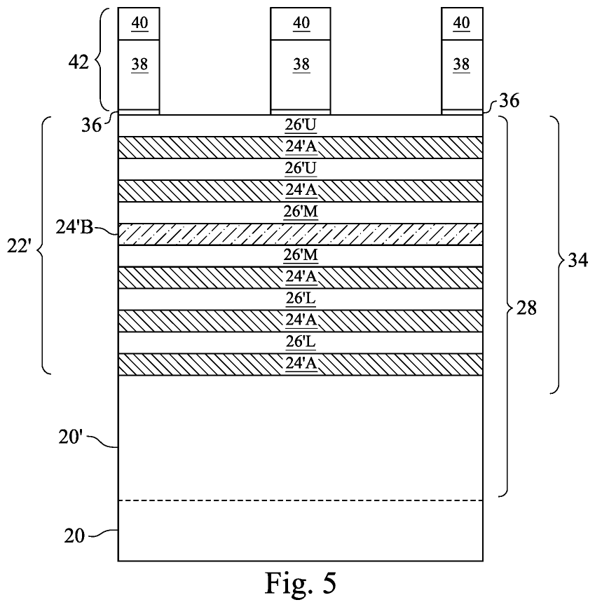

Next, the mask layer 40 may be patterned through photolithography and etching processes to form a mask, which is then used to etch and pattern dummy gate layer 38, and possibly dummy dielectric layer 36. A resulting structure is shown in FIG. 5, which illustrates a cross-section along the lengthwise direction of semiconductor strip 28. The remaining portions of mask layer 40, dummy gate layer 38, and dummy dielectric layer 36 form dummy gate stacks 42. The respective process is illustrated as process 208 in the process flow 200 as shown in FIG. 17.

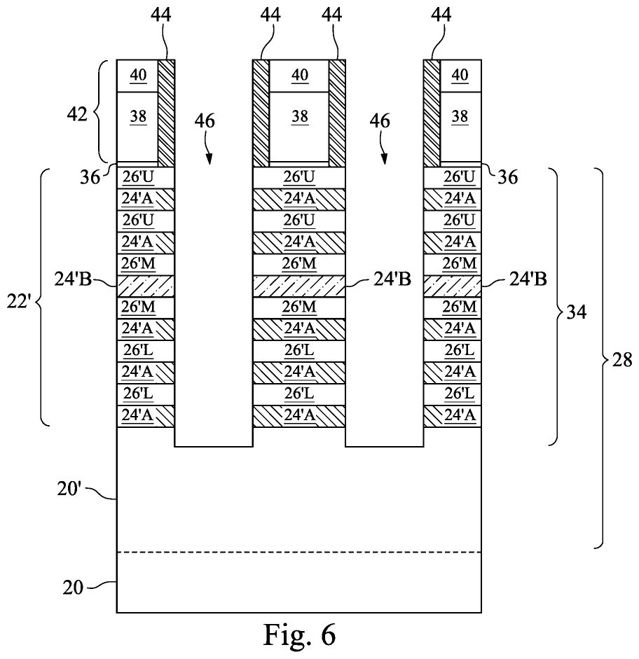

In FIG. 6, gate spacers 44 are formed over the multi-layer stacks 22′ and on exposed sidewalls of dummy gate stacks 42. The respective process is illustrated as process 210 in the process flow 200 as shown in FIG. 17. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 are also formed.

Source/drain recesses 46 are formed in semiconductor strips 28. The respective process is also illustrated as process 210 in the process flow 200 as shown in FIG. 17. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

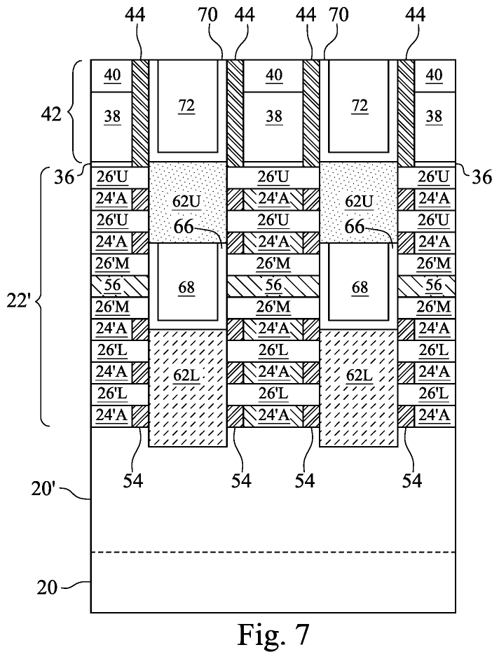

In FIG. 7, inner spacers 54 and dielectric isolation layers 56 are formed. The respective process is illustrated as process 212 in the process flow 200 as shown in FIG. 17. The formation of inner spacers 54 and dielectric isolation layers 56 may include an etching process that laterally etches the dummy nanostructures 24′A (FIG. 6) and removes the dummy nanostructure 24′B.

The etching process may be isotropic and may be selective to the material of the dummy nanostructures 24′A, so that the dummy nanostructures 24′A are etched at a faster rate than the semiconductor nanostructures 26′U and 26′L. The etching process may also be selective to the material of the dummy nanostructures 24′B, so that the dummy nanostructures 24′B are etched at a faster rate than the dummy nanostructures 24′A. In this manner, the dummy nanostructures 24′B may be completely removed from between the lower semiconductor nanostructures 26′L (collectively) and the upper semiconductor nanostructures 26′U (collectively) without completely removing the dummy nanostructures 24′A.

In some embodiments where the dummy nanostructures 24′B are formed of germanium or silicon germanium with a high germanium atomic percentage, the dummy nanostructures 24′A are formed of silicon germanium with a low germanium atomic percentage, and the semiconductor nanostructures 26′ (including 26′M, 26′U and 26′L) are formed of silicon free from germanium, the etch process may comprise a dry etch process using chlorine gas, with or without a plasma. Because the dummy gate stacks 42 warp around sidewalls of the semiconductor nanostructures 26′ (see FIG. 2), the dummy gate stacks 42 may support the upper semiconductor nanostructures 26′U so that the upper semiconductor nanostructures 26′U do not collapse upon removal of the dummy nanostructures 24′B. Further, although sidewalls of the dummy nanostructures 24′A are illustrated as being straight after the etching, the sidewalls may be concave or convex.

Inner spacers 54 are formed on sidewalls of the recessed dummy nanostructures 24′A, and dielectric isolation layers 56 are formed between the upper semiconductor nanostructures 26′U (collectively) and the lower semiconductor nanostructures 26′L (collectively). In the subsequent formation of source/drain regions, the inner spacers 54 may act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26′U (collectively) from the lower semiconductor nanostructures 26′L (collectively). Furthermore, middle semiconductor nanostructures 26′M and dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, and between the upper and lower semiconductor nanostructures 26′U and 26′L, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26′U and 26′L (thus forming the dielectric isolation layers 56).

As also illustrated by FIG. 7, lower epitaxial source/drain regions 62L and upper and 62U are formed. The lower epitaxial source/drain regions 62L are formed in the lower portions of the source/drain recesses 46. The respective process is illustrated as process 222 in the process flow 200 as shown in FIG. 17. The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like.

The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26′U may be masked to prevent undesired epitaxial growth on the upper semiconductor nanostructures 26′U. After the lower epitaxial source/drain regions 62L are grown, the masks on the upper semiconductor nanostructures 26′U may then be removed.

A first Contact Etch Stop Layer (CESL) 66 and a first Inter-Layer Dielectric (ILD) 68 are formed over the lower epitaxial source/drain regions 62L. The respective process is illustrated as process 224 in the process flow 200 as shown in FIG. 17. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Upper epitaxial source/drain regions 62U are then formed in the upper portions of the source/drain recesses 46. The respective process is illustrated as process 226 in the process flow 200 as shown in FIG. 17. The upper epitaxial source/drain regions 62U may be epitaxially grown from exposed surfaces of the upper semiconductor nanostructures 26′U. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. For example, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The respective process is illustrated as process 228 in the process flow 200 as shown in FIG. 17. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

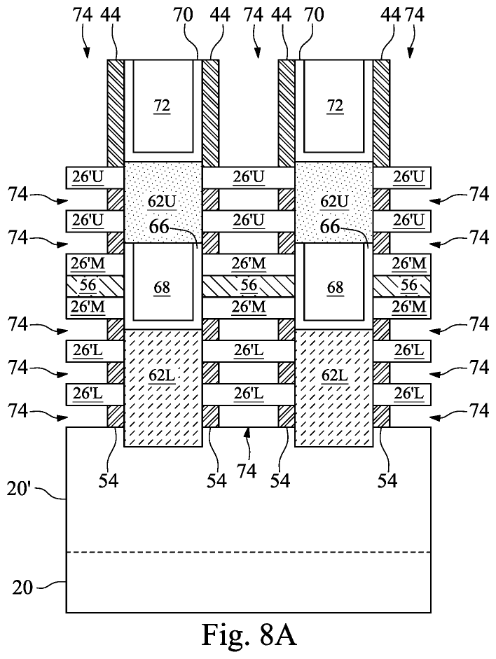

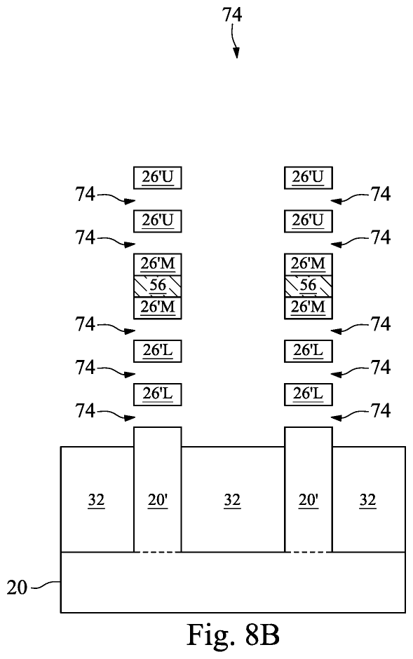

Replacement gate stacks are then formed to replace the dummy gate stacks. The dummy gate stacks 42 are first removed in one or more etching processes, so that recesses 74 are formed, as shown in FIGS. 8A and 8B. The respective process is illustrated as process 230 in the process flow 200 as shown in FIG. 17. Each of recesses 74 exposes and/or overlies portions of multi-layer stacks 22′.

The remaining portions of the dummy nanostructures 24′A are then removed through etching, so that recesses 74 extend between the semiconductor nanostructures 26′. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

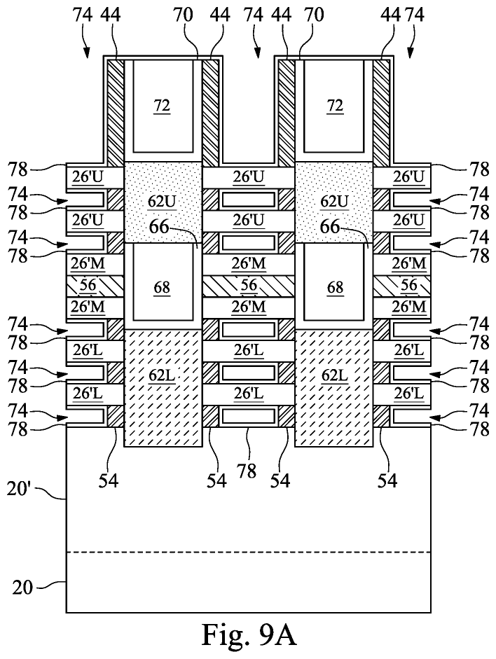

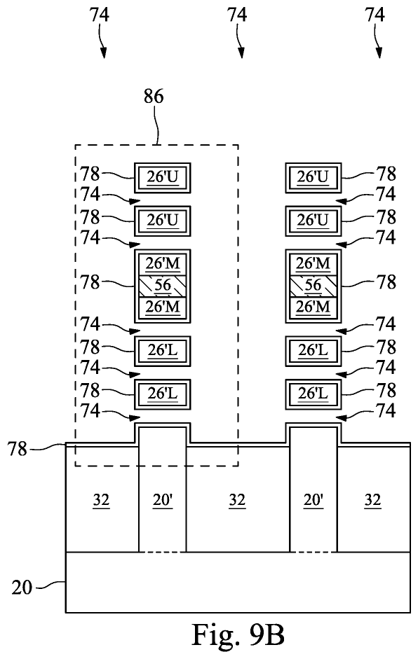

In FIGS. 9A and 9B, gate dielectrics 78 are formed as parts of a conformal liner in recesses 74, and are formed on the exposed semiconductor nanostructures 26′. The respective process is illustrated as process 232 in the process flow 200 as shown in FIG. 17. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

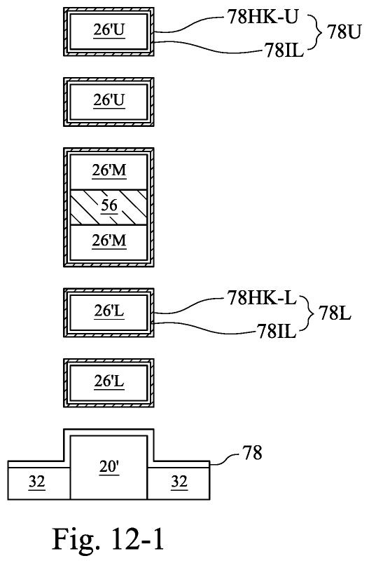

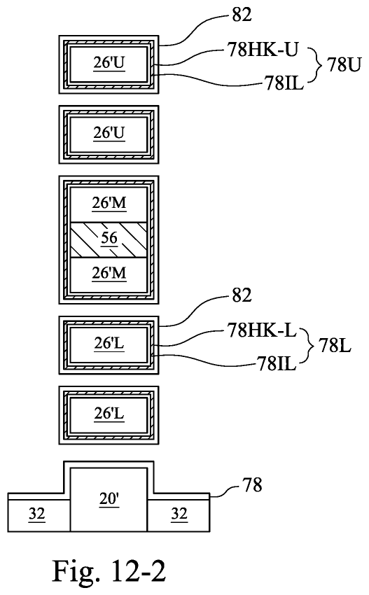

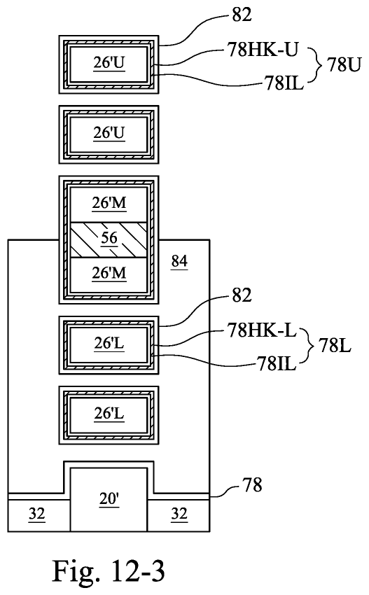

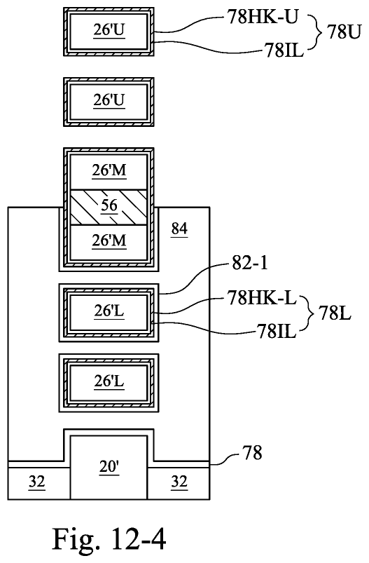

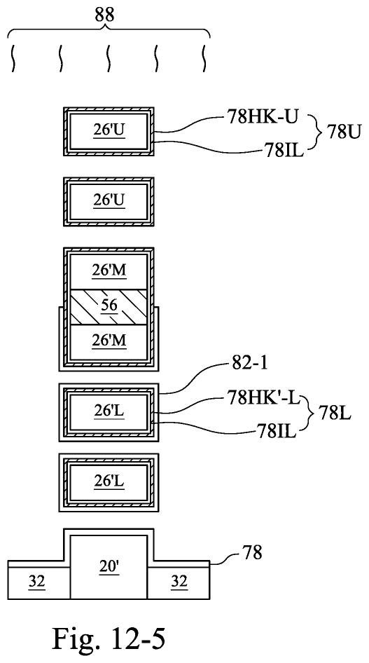

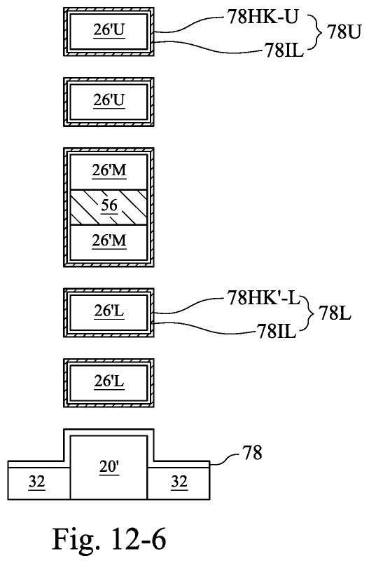

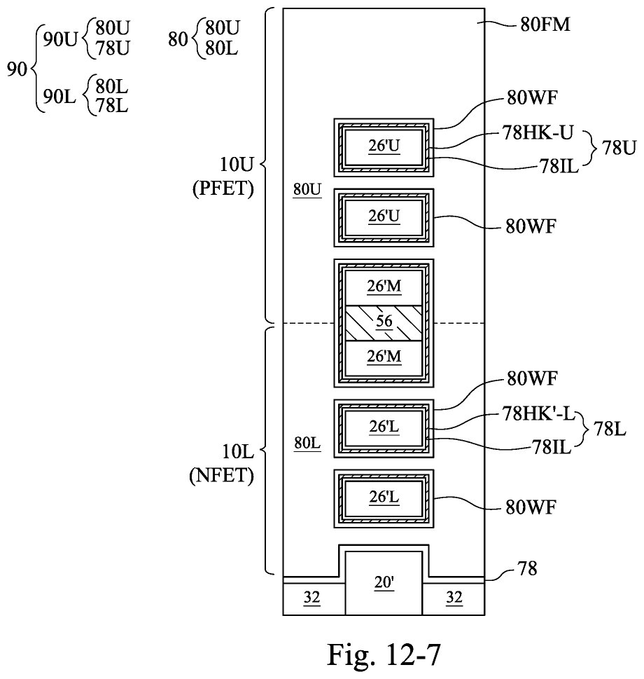

FIGS. 12-1 through 12-7, FIGS. 13-1 through 13-6, FIGS. 14-1 through 14-6, and FIGS. 15-1 through 15-6 illustrate various embodiments for forming the gate stacks of the CEFTs, which share common gate electrodes 80 (including 80U and 80L). FIGS. 12-1 through 12-7 illustrate the formation of an ex-situ doping of a dipole dopant into the high-k dielectric layers of a lower FET. Referring to FIG. 12-1, the region 86 as shown in FIG. 9B is illustrated. In the illustrated example, the upper FET to be formed is a PFET, while the lower FET to be formed is an NFET.

Gate dielectrics 78 (including 78U and 78L) are formed to encircle nanostructures 26′U, 26M, and 26′L. Each of the gate dielectrics 78 may include an interfacial layer 78IL, which may be formed of or comprise a group IV element, a group III element, and/or a group V element. Interfacial layer 78IL may include an oxide such as silicon oxide or a metal oxide, a silicate such as a metal silicate, combinations thereof, multi-layers thereof, or the like. The interfacial layer 78IL may have a thickness in the range between about 0.5 nm and about 2 nm. The interfacial layer 78IL may be formed of a thermal oxidation process and/or a deposition process.

The gate dielectrics 78 may also include high-k dielectric layers 78HK (including 78HK-U and 78HK-L), which have a high dielectric constant (high-k) value greater than, for example, about 7.0, about 21, or higher. High-k dielectric layers 78HK may be formed of or comprise a metal oxide or a silicate of a metal selected from hafnium, zirconium, barium, titanium, lead, and combinations thereof. The formation methods of high-k dielectric layers 78HK may be selected from Molecular-Beam Deposition (MBD), ALD, PECVD, and the like. High-k dielectric layers 78HK may have a thickness in the range between about 1 nm and about 5 nm. The gate dielectrics 78 in the upper FET region and the lower FET region are formed in common processes. For clarification, the gate dielectrics 78 are denoted as 78U and 78L. The gate dielectrics 78, at the time they are formed, may be free from the n-type dipole dopant as will be discussed subsequently, or may include a small amount of dipole dopant for adjusting the threshold voltage.

Referring to FIG. 12-2, dipole film 82 is deposited on the gate dielectrics 78. The deposition process may include a conformal deposition process such as ALD, CVD, or the like. The respective process is illustrated as process 234 in the process flow 200 as shown in FIG. 17. Dipole film 82 comprises a n-type dipole dopant, which when incorporated into the gate dielectrics of n-type FETs, may reduce the effective work functions and hence reduce the threshold voltages of the corresponding n-type FETs. The n-type dipole dopant, when incorporated into the gate dielectrics of p-type FETs, may reduce the effective work functions and hence increase the threshold voltages of the corresponding p-type FETs. In accordance with some embodiments, dipole film 82 may comprise a material selected from one or more of an oxide(s), a nitride(s), and/or a carbide(s) of an n-type dipole dopant(s) such as La, Sr, Y, Er, Sc, Mg, or the like, or combinations thereof. The thickness of dipole film 82 may be in the range between about 0.3 nm and about 1.5 nm.

Referring to FIG. 12-3, dummy filling-region 84 is formed. The respective process is illustrated as process 236 in the process flow 200 as shown in FIG. 17. In accordance with some embodiments, dummy filling-region 84 is formed of a material that has a high etching selectivity to the exposed features of the structure as shown in FIGS. 9A and 9B. For example, dummy filling-region 84 may be formed of SiN, SiOC, SiO, SiOCN, SiCN, AlO, AlN, CoN, or the like. The formation process may include depositing a filling material to fully fill recesses 74 (FIG. 9B), performing a planarization process to level the top surface of the filling material, and etching back the filling material. The etching process is controlled, so that the top surfaces of dummy filling-region 84 is at a level between the top surface level and the bottom surface level of dielectric isolation layer 56, while the top surface may be slightly higher or lower. Dummy filling-region 84 may have a planar top surface within process variation.

Next, an isotropic etching process is performed, as shown in FIG. 12-4. The respective process is illustrated as process 238 in the process flow 200 as shown in FIG. 17. The etching process may be a wet etching process or a dry etching process, which are isotropic. The etching chemical is selected to etch dipole film 82, and stops on high-k dielectric layers 78HK. Accordingly, the portions of dipole film 82 on upper semiconductor nanostructures 26′U and the upper one of the middle semiconductor nanostructures 26′M are removed. The portions of dipole film 82 on lower semiconductor nanostructures 26′L and the lower one of the middle semiconductor nanostructures 26′M are protected from being removed.

In a subsequent process, dummy filling-region 84 is removed. The respective process is illustrated as process 240 in the process flow 200 as shown in FIG. 17. The resulting structure is shown in FIG. 12-5. After the removal of dummy fill-region 84, the dipole film 82 in the lower FET region is exposed, while in the upper FET region, there is no dipole film.

Further referring to FIG. 12-5, anneal process 88 is performed to drive the dipole dopants in the dipole film 82 into the respective underlying high-k dielectric layers 78HK-L. The resulting high-k dielectric layers with the dipole dopant incorporated are referred to as high-k dielectric layers 78HK′-L hereinafter. The respective process is illustrated as process 242 in the process flow 200 as shown in FIG. 17. The anneal process 88 may be performed in a process gas such as N₂, He, NH₃, Ar, or the like, or the mixture thereof. In accordance with some embodiments, anneal process 88 is performed through a soak anneal process, a spike rapid thermal anneal process, or the like. When the soak anneal process is adopted, the annealing duration may be in the range between about 5 seconds and about 5 minutes. The annealing temperature may be in the range between about 500° C. and about 850° C. When the spike rapid thermal anneal process is adopted, the annealing duration may be in the range between about 0.5 seconds and about 3.5 seconds. The annealing temperature may be in the range between about 700° C. and about 850° C.

The high-k dielectric layers 78HK′-L have a dipole dopant atomic percentage AP78-L greater than the dipole dopant atomic percentage AP78-U in the high-k dielectric layer 78HK-U. High-k dielectric layer 78HK-U may comprise, or may be free from, the dipole dopant, depending on whether the high-k dielectric layer 78HK-U as deposited includes the dipole dopant or not.

In accordance with some embodiments, the difference in dipole dopant atomic percentages (AP78-L-AP78-U) may be greater than about 0.5 percent, and may be in the range between about 10 percent. The desirable dipole dopant atomic percentage AP78-L depends on the desirable threshold voltage of the resulting NFET. The lower the threshold voltage of the NFET is desired, the higher the dipole dopant atomic percentage AP78-L will be. The desirable dipole dopant atomic percentage AP78-L is achieved by adjusting the thickness of dipole film 82, and the greater the thickness is, the higher the dipole dopant atomic percentage AP78-L is.

Dipole film 82 is then removed in an isotropic etching process. The resulting structure is shown in FIG. 12-6, wherein high-k dielectric layers 78HK-U and 78HK′-L are exposed.

FIG. 12-7 illustrates the formation of gate electrodes in common processes for the upper FET and the lower FET. The respective process is illustrated as process 244 in the process flow 200 as shown in FIG. 17. Gate dielectrics 78 and the respective gate electrodes 80 are collectively referred to as gate stacks 90, which include upper gate stack 90U and lower gate stack 90L. The resulting upper FET 10U and lower FET 10L share a common gate electrode 80. The upper portion of the gate electrode 80 that is higher than dielectric isolation layer 56 is referred to as upper gate electrode 80U. The lower portion of the gate electrode that is lower than dielectric isolation layer 56 is referred to as lower gate electrode 80L.

Gate electrodes 80 may include a plurality of layers include TiN, TaN, or the like, and may include one or more work function layers 80WF and filling metal regions 80FM. The thickness of each of the layers in gate electrode 80 may be in the range between about 2 nm and about 5 nm. Filling metal regions 80FM may comprise tungsten, ruthenium, cobalt, combinations thereof, multi-layers thereof, or the like.

The work function layers 80WF encircling each of the gate dielectrics 78 may be physically separate from the work function layers 80WF encircling other ones of the gate dielectrics 78. In which case, filling metal regions 80FM (such as tungsten, cobalt, or the like) may fill the spaces between the work function layers 80WF on neighboring gate dielectrics 78. Alternatively, the work function layers 80WF encircling each of the gate dielectrics 78 may be physically joined to the work function layers 80WF encircling other ones of the gate dielectrics 78.

In accordance with some embodiments, the work function layers 80WF have a p-type work function, which is higher than about 4.6 eV, and may be in the range between about 4.6 eV and about 5.2 eV. The n-type FETs, however, prefer n-type work functions, which have low work function values, for example, smaller than about 4.5 eV, or between about 4.0 eV and about 4.5 eV. In accordance with the embodiments of the present disclosure, this conflict is solved by doping the high-k dielectric layers of the NFETs with the n-type dipole dopant, as discussed above, so that the effective work function of the p-type work function layer in the NFETs is reduced to the n-type work function range, for example, between about 4.0 eV and about 4.5 eV. The PFET, on the other hand, is not doped with the n-type dipole dopant, and hence its work function layer 80WF remain to have a p-type effective work function.

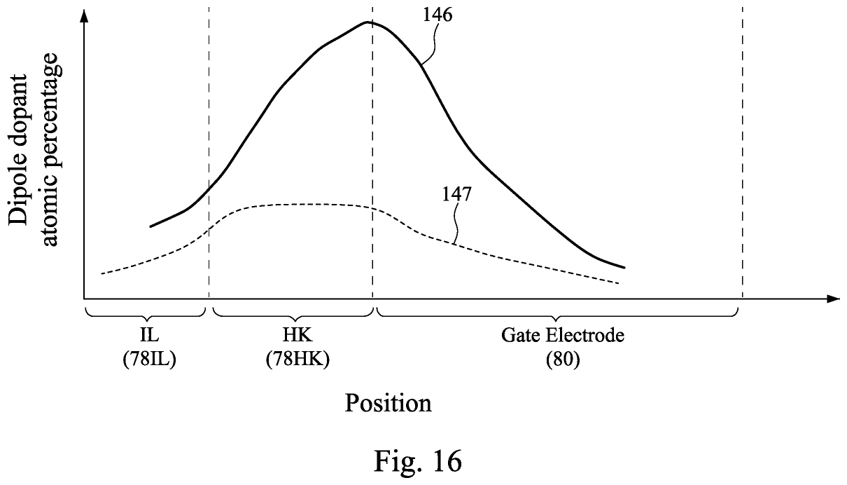

It is appreciated that the dipole dopants are diffused from dipole film 82, which is removed after the drive-in process. Accordingly, after the removal of the dipole film 82, the peak dipole dopant atomic percentage may occur at the outer surface of the high-k dielectric layers 78HK′-L, which will be in contact with the later-formed gate electrode 80. Line 146 in FIG. 16 schematically illustrates the dipole dopant atomic percentages in lower FET 10L as a function of positions, where the dipole dopant distribution in interfacial layer 78IL, high-k dielectric layer 78HK, and gate electrode 80 are illustrated. The peak dipole dopant atomic percentages may occur at the interface between high-k dielectric layers 78 and the corresponding gate electrodes 8o, or may slightly shift left or right, for example, with shifting distances smaller than about 1 nm. Also, the dipole dopant atomic percentages are steeper in gate electrode 80 than in interfacial layer 78IL and high-k dielectric layer 78HK.

Line 147 schematically illustrates the dipole dopant distribution in upper FET 10U when high-k dielectric layer 78HK (78HK-U), at the time it is deposited, includes an n-type dipole dopant already. Otherwise, the Line 147 will be at the zero atomic percentage line. Line 147 may have a flat top in high-k dielectric layer 78HK (78HK-U), and the dropping in interfacial layer 78IL and gate electrode 80 (80U) may have similar steepness.

Since the dipole film 82 is removed, it is volume-less in the resulting FET, and will not occupy the space between nanostructures. By adopting the same materials for forming the gate electrodes for both of the PFETs and NFETs, there is no need to etch the gate electrodes from the upper FETs, and then form the gate electrodes again for the upper FETs. The etching of the gate electrodes may damage the high-k dielectric layers. Accordingly, in accordance with the embodiments of the present disclosure, the damage to the high-k dielectric layers is avoided due to the use of common gate electrodes.

FIGS. 13-1 through 13-6 illustrate the formation of CFETs in accordance with alternative embodiments. These embodiments are similar to the embodiments in FIGS. 12-1 through 12-7, except that the dipole dopant is in-situ (rather than ex-situ) doped into high-k dielectric layers 78HK. Unless specified otherwise, the materials, the structures, and the formation processes in accordance with these embodiments (and the embodiments shown in FIGS. 14-1 through 14-6 and FIGS. 15-1 through 15-6) are essentially the same as the embodiments shown in FIGS. 12-1 through 12-7, and may not repeated herein.

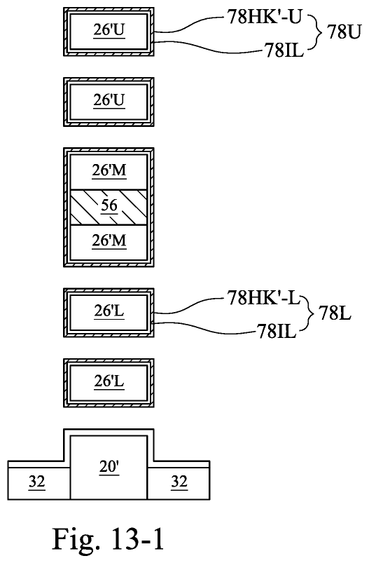

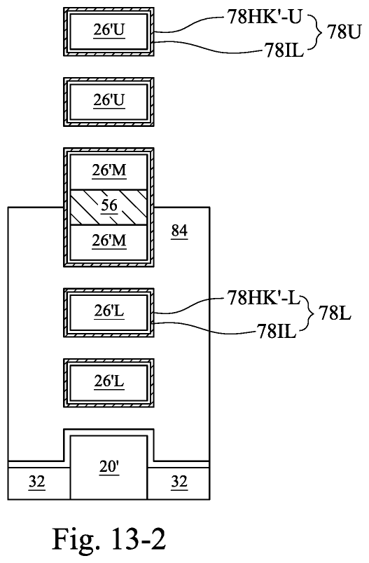

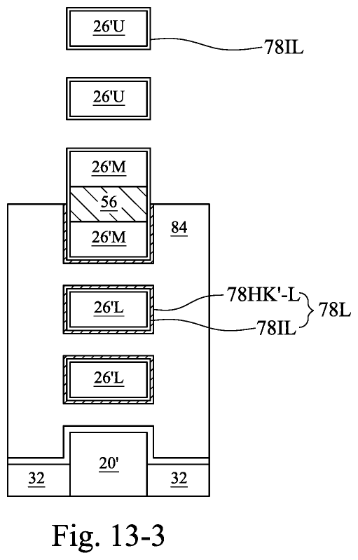

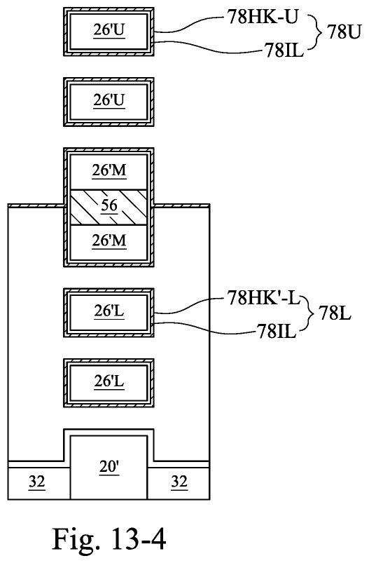

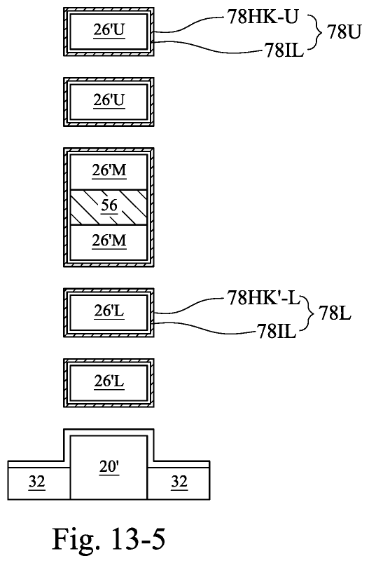

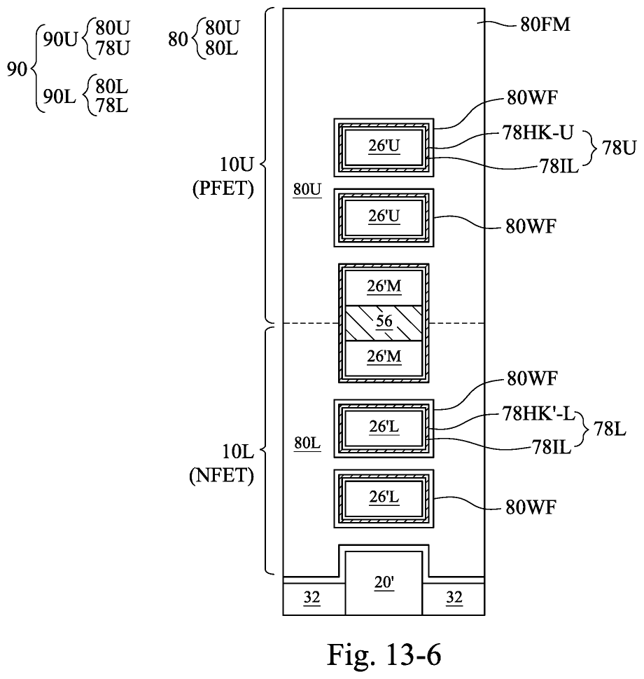

Referring to FIG. 13-1, gate dielectrics 78 are formed in the upper FET region and the lower FET region. The formation of gate dielectrics 78 includes forming interfacial layers 78IL, and depositing high-k dielectric layers 78HK′ (including 78HK′-U and 78HK′-L). High-k dielectric layers 78HK′ may include the high-k dielectric materials such as hafnium, zirconium, barium, titanium, lead, or combinations thereof. During the deposition, an n-type dipole dopant is in-situ doped. For example, the n-type dipole dopant may include La, Sr, Y, Er, Sc, Mg, or the like, or combinations thereof.

By incorporating the n-type dipole dopant, the effective work function of the lower FET is inverted, and falls into the range of the n-type work function. In accordance with some embodiments, the dipole dopant atomic percentage in high-k dielectric layers 78HK′ may be in the range between about 0.5 percent and about 10 percent.

Referring to FIG. 13-2, dummy filling-region 84 is formed, and is etched back to mask the lower FET region, while leaving the upper FET region unmasked. FIG. 13-3 illustrates the removal of high-k dielectric layers 78HK′ in the upper FET regions through etching. Next, as shown in FIG. 13-4, high-k dielectric layers 78HK-U are deposited in a conformal process. The high-k dielectric material in high-k dielectric layers 78HK-U may be selected from the same candidate group of materials for forming high-k dielectric layers 78HK′-L, and may be the same as, or different from, that in high-k dielectric layers 78HK′-L. Furthermore, high-k dielectric layers 78HK-U may be free from the n-type dipole dopant, or alternatively, in-situ doped with a small amount of the n-type dopant. The total n-type dipole dopant atomic percentage in high-k dielectric layers 78HK-U is lower than that in high-k dielectric layers 78HK′-L. The n-type dipole dopant (if in-situ doped) in high-k dielectric layers 78HK-U may be the same as or different from the n-type dipole dopant in high-k dielectric layers 78HK′-L.

FIG. 13-5 illustrates the removal of dummy filling-region 84, and the removal of the portion of the high-k dielectric layers on dummy filling-region 84.

FIG. 13-6 illustrates the formation of the common gate electrode 80 for CFETs. Gate electrode 80 includes gate electrode 80U and 80L that are formed in the same formation processes. The resulting upper FET 10U is a PFET, and the lower FET 10L is an NFET. The effective work function of the lower FET 10L is inverted as being of n-type. The effective work function of the upper FET 10U remains to be of p-type. Since the dipole dopant is in-situ doped, it may have a uniform atomic percentage at the time high-k dielectric layers 78HK′-L are formed. In the structure as shown in FIG. 13-6, the dipole dopant may have a peak atomic percentage in (and possibly in the middle) of the respective high-k dielectric layers 78HK′-L, similar to line 147 in FIG. 16. The peak may also be flatter than the diffused dipole dopant.

FIGS. 14-1 through 14-2 illustrate the formation of CFETs in accordance with yet alternative embodiments. These embodiments are similar to the embodiments in FIGS. 12-1 through 12-7, with the dipole dopant being ex-situ doped. The dipole dopant, however, is a p-type dopant, and the work function layer of the resulting FETs has an n-type work function, with the effective work function being adjusted through dipole doping.

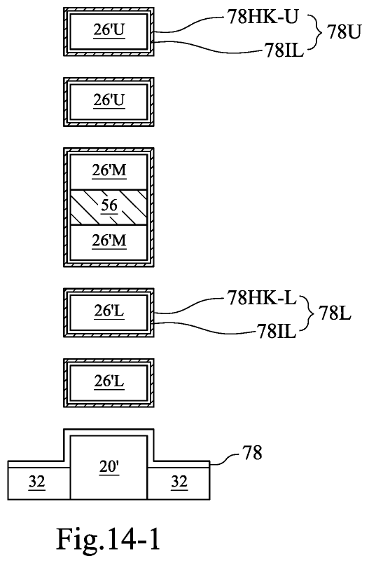

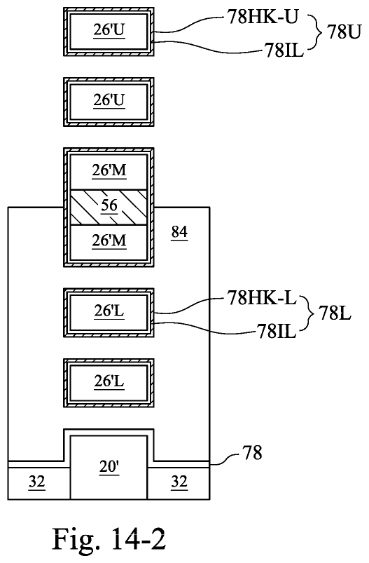

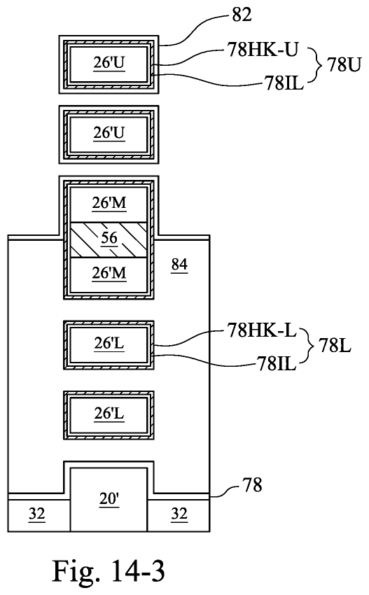

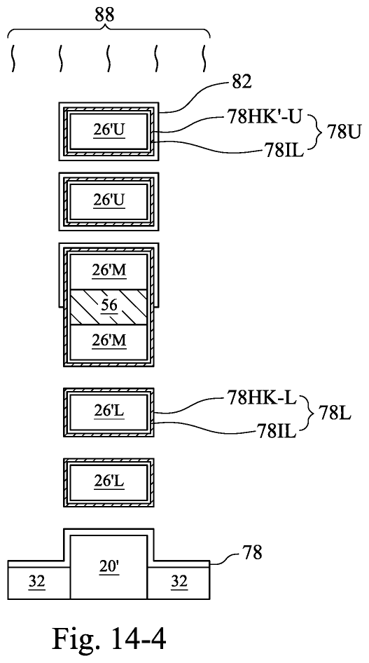

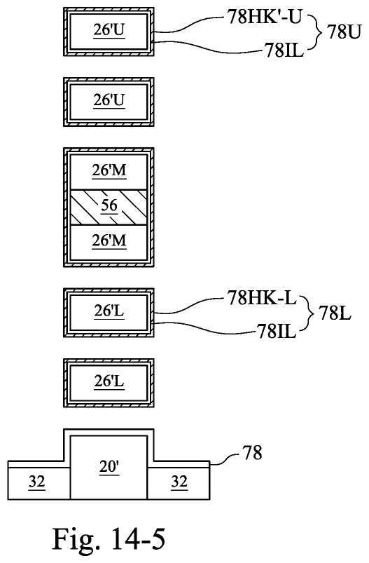

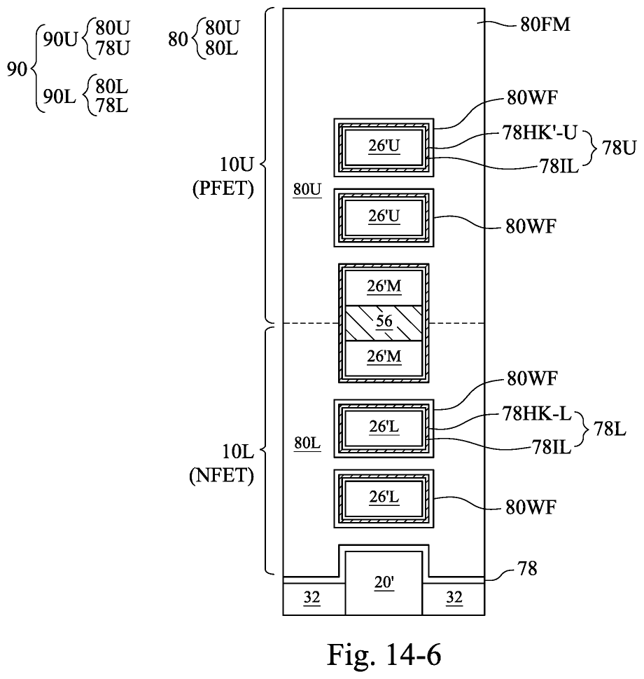

Referring to FIG. 14-1, gate dielectrics 78 (including 78U and 78L) are formed. The high-k dielectrics 78HK may be free or substantially free from p-type dopants, as will be discussed referred to FIG. 14-3. Next, as shown in FIG. 14-2, dummy filling-region 84 is formed to mask the lower FET region, while leaving the upper FET region open.

Dipole film 82 is then formed on the gate dielectrics 78, as shown in FIG. 14-3. Dipole film 82 includes a p-type dopant, which has the function of increasing the effect work function of the resulting gate, and hence can increase the threshold voltage of NFETs, and reduce the threshold voltage of PFETs. In accordance with some embodiments, the p-type dipole dopant includes Al, Zn, Ga, or the like, or combinations thereof. The atomic percentage of the p-type dipole dopant is adequate to invert the work function of the subsequently formed n-type work function layer, and causing the effective work function of the resulting gate PFET to be p-type.

Referring to FIG. 14-4, dummy filling-region 84 is removed, and the portion of dipole film 82 on dummy filling-region 84 is also removed. Anneal process 88 is then performed to drive the dipole dopant into the respective underlying high-k dielectric layers, which are denoted as high-k dielectric layers 78HK′-U. The p-type dipole dopant atomic percentage in the high-k dielectric layers 78HK′-U may be in the range between about 0.5 percent and about 10 percent. High-k dielectric layers 78HK-L on the other hand, has no dipole dopant diffused in.

FIG. 14-5 illustrates the removal of dipole film 82 through etching, hence exposing high-k dielectric layers 78HK′-U.

FIG. 14-6 illustrates the formation of the common gate electrode 80 for CFETs. Gate electrode 80 includes gate electrode 80U and 80L that are formed in the same formation process. The resulting upper FET 10U is a PFET, and the lower FET 10L is an NFET. The work function layer 80WF has an n-type work function lower than about 4.5 eV, and may be in the range between about 4.5 eV and about 4.5 eV. The work function layer 80WF may include TiAl, TiAlN, AlN, or the like. The effective work function of the upper FET 10U is inverted as being of p-type, and is higher than about 4.6 eV. The effective work function of the lower FET 10L remains to be of n-type.

FIGS. 15-1 through 15-6 illustrate the formation of CFETs in accordance with alternative embodiments. These embodiments are similar to the embodiments in FIGS. 13-1 through 13-6, except that a p-type dipole dopant, rather than an n-type dopant, is in-situ doped. The work function layer of the resulting FETs has an n-type work function.

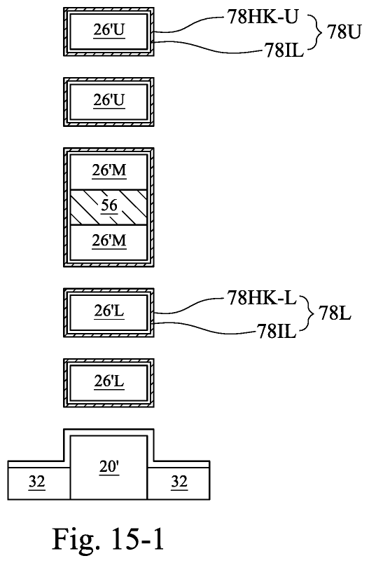

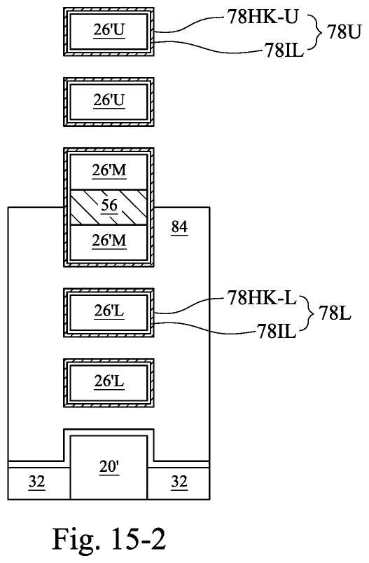

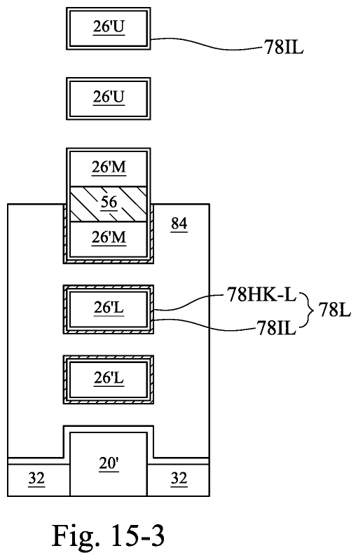

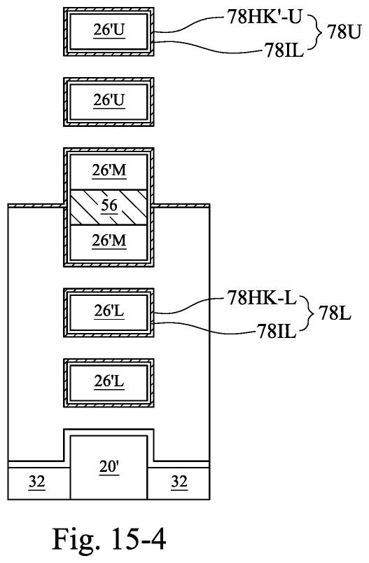

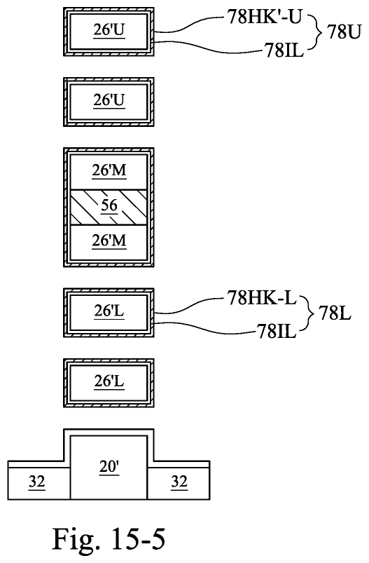

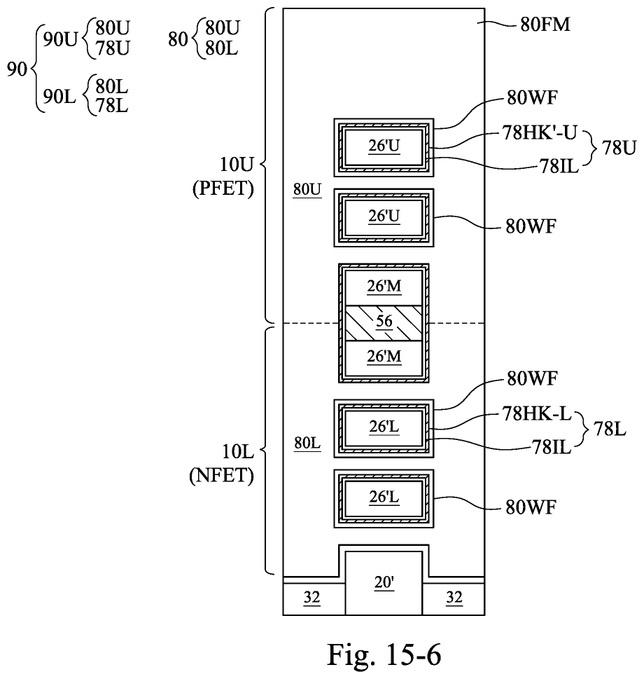

Referring to FIG. 15-1, gate dielectrics 78 are formed in the upper FET region and the lower FET region. The formation of gate dielectrics 78 includes forming interfacial layers 78IL, and depositing high-k dielectric layers 78HK (including 78HK-U and 78HK-L). High-k dielectric layers 78HK may include the high-k dielectric materials such as hafnium, aluminum, zirconium, barium, titanium, lead, or combinations thereof. During the deposition, no p-type dipole dopant is in-situ incorporated, or a p-type dipole dopant may be doped to a small atomic percentage. In the case the high-k dielectric layers 78HK include the p-type dopant, the atomic percentage of the p-type dopant is not enough to invert the work function of the subsequently formed n-type work function layer to have a p-type effective work function.

Referring to FIG. 15-2, dummy filling-region 84 is formed, and is etched back to mask the lower FET region, while leaving the upper FET region unmasked. FIG. 15-3 illustrates the removal of high-k dielectric layers 78HK in the upper FET regions. Next, as shown in FIG. 15-4, high-k dielectric layers 78HK′-U are deposited in a conformal process. The main high-k dielectric material in high-k dielectric layers 78HK′-U may be selected from the same candidate group of materials for forming high-k dielectric layers 78HK-L, and may be the same as or different from that in high-k dielectric layers 78HK-L. High-k dielectric layers 78HK′-U includes a p-type dipole dopant, which is in-situ doped during the deposition of high-k dielectric layers 78HK′-U. The total p-type dipole dopant atomic percentage in high-k dielectric layers 78HK′-U is higher than that in high-k dielectric layers 78HK-U, and may be in the range between about 0.5 percent and about 10 percent.

FIG. 15-5 illustrates the removal of dummy filling-region 84, and the removal of the portion of the high-k dielectric layers 78HK′ on dummy filling-region 84.

FIG. 15-6 illustrates the formation of the common gate electrode 80 for CFETs. Gate electrode 80 includes gate electrode 80U and 80L that are formed in the same formation process. The resulting upper FET 10U is a PFET, and the lower FET 10L is an NFET. The effective work function of the upper FET 10U is inverted as being of p-type. The effective work function of the lower FET 10L remains to be of n-type. Since the p-type dipole dopant is in-situ doped, it may have a uniform atomic percentage at the time high-k dielectric layers 78HK′-U are formed. In the structure as shown in FIG. 15-6, the p-type dipole dopant may have a profile similar to that of line 147 in FIG. 16. The peak may also be flatter than the diffused dipole dopant.

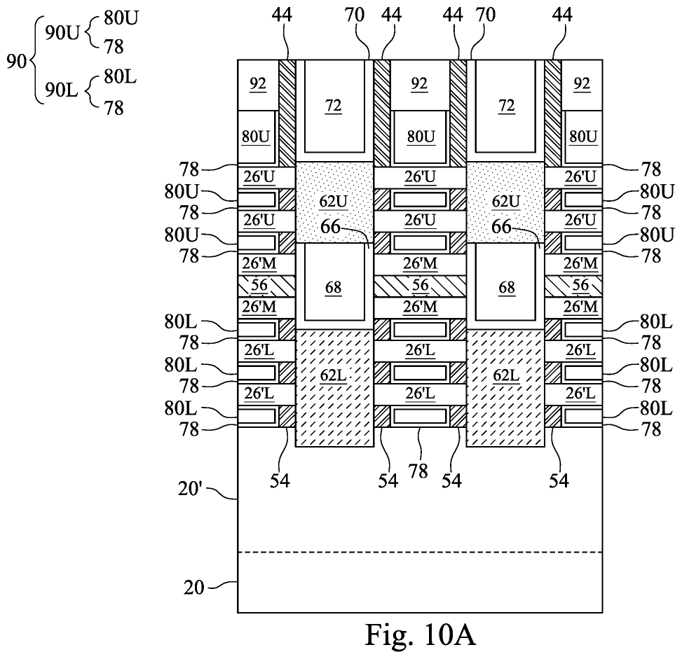

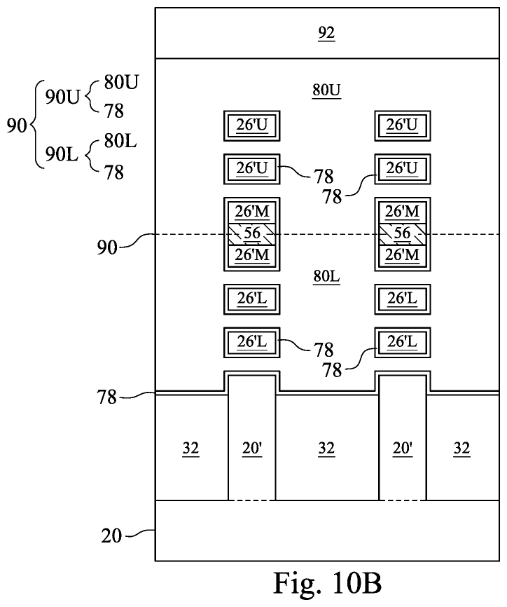

FIGS. 10A and 10B illustrate the cross-sectional views of an example CFET as formed in preceding processes. The common gate electrode 80 includes upper electrode 80U and lower electrode 80L, which are formed in the processes and using the materials as discussed above.

In FIGS. 10A and 10B, gate masks 92 are formed over the dummy gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

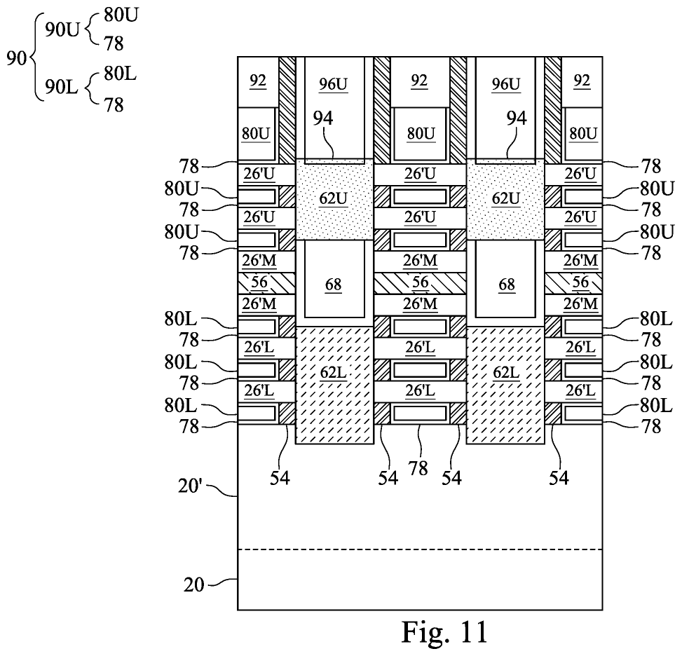

Next, referring to FIG. 11, silicide regions 94 and source/drain contact plugs 96U are formed to electrically couple to the source/drain regions 62U.

The embodiments of the present disclosure have some advantageous features. A same work function material, which may be a p-type work function material or an n-type work function material, is used to form both of a PFET and an NFET in a same CFET structure. By in-situ or ex-situ doping a dipole dopant (such as an n-type dipole dopant or a p-type dopant) into the gate dielectric of one of the PFET and the NFET, the effective work function of one of the PFET and the NFET is inverted to have a desirable value.

In accordance with some embodiments, a method comprises forming a first semiconductor channel region and a second semiconductor channel region, wherein the second semiconductor channel region overlaps the first semiconductor channel region; forming a first gate dielectric on the first semiconductor channel region; forming a second gate dielectric on the second semiconductor channel region; incorporating a dipole dopant into a first one of the first gate dielectric and the second gate dielectric to a higher atomic percentage, wherein a second one of the first gate dielectric and the second gate dielectric has a lower atomic percentage of the dipole dopant; and forming a gate electrode on both of the first gate dielectric and the second gate dielectric, wherein the gate electrode and the first gate dielectric form parts of a first transistor, and the gate electrode and the second gate dielectric form parts of a second transistor.

In an embodiment, the incorporating the dipole dopant comprises depositing a dipole film on the first gate dielectric and the second gate dielectric; removing the dipole film from the second gate dielectric; driving the dipole dopant into the first gate dielectric; and removing the dipole film. In an embodiment, the incorporating the dipole dopant is in-situ performed when the first gate dielectric and the second gate dielectric are deposited.

In an embodiment, the first one is deposited as having the lower atomic percentage of the dipole dopant, and the method further comprises replacing the second gate dielectric with another gate dielectric having the higher atomic percentage of the dipole dopant. In an embodiment, when the first one is deposited as having the higher atomic percentage of the dipole dopant, and the method further comprises replacing the second gate dielectric with another gate dielectric having the lower atomic percentage of the dipole dopant.

In an embodiment, the gate electrode comprises a p-type metal, and wherein the dipole dopant is an n-type dipole dopant. In an embodiment, the gate electrode comprises an n-type metal, and wherein the dipole dopant is a p-type dipole dopant. In an embodiment, the first transistor is an n-type transistor, and the second transistor is a p-type transistor. In an embodiment, the dipole dopant is an n-type dopant selected from the group consisting of La, Sr, Y, Er, Sc, Mg, and combinations thereof. In an embodiment, the dipole dopant is a p-type dopant selected from the group consisting of Al, Zn, Ga, and combinations thereof.

In accordance with some embodiments, a structure comprises a lower transistor comprising a first channel region; a first gate dielectric on the first channel region, wherein the first gate dielectric has a first atomic percentage of a dipole dopant; and a first gate electrode on the first gate dielectric; and an upper transistor, wherein a first transistor of the lower transistor and the upper transistor is an n-type transistor, and wherein a second transistor of the lower transistor and the upper transistor is a p-type transistor, and wherein the upper transistor comprises a second channel region overlapping the first channel region; a second gate dielectric on the second channel region, wherein the second gate dielectric has a second atomic percentage of the dipole dopant, and wherein the second atomic percentage is different from the first atomic percentage; and a second gate electrode on the second gate dielectric, wherein the first gate electrode and the second gate electrode are parts of a same continuous gate electrode.

In an embodiment, the first transistor is the n-type transistor, and the second transistor is the p-type transistor. In an embodiment, the dipole dopant is an n-type dopant selected from the group consisting of La, Sr, Y, Er, Sc, Mg, and combinations thereof. In an embodiment, the dipole dopant is a p-type dopant selected from the group consisting of Al, Zn, Ga, and combinations thereof. In an embodiment, the first gate dielectric and the second gate dielectric comprise same high-k dielectric materials. In an embodiment, the first gate dielectric and the second gate dielectric comprise different high-k dielectric materials.

In accordance with some embodiments, a structure comprises a lower transistor comprising a first channel region; a first gate dielectric on the first channel region, wherein the first gate dielectric comprises a high-k dielectric material; and a first source/drain region connecting to the first channel region; and an upper transistor comprising a second channel region overlapping the first channel region; a second gate dielectric on the second channel region, wherein the second gate dielectric comprises the high-k dielectric material and a dipole dopant, wherein a first atomic percentage of the dipole dopant in the first gate dielectric is lower than a second atomic percentage of the dipole dopant in the second gate dielectric; and a second source/drain region connecting to the second channel region, wherein the second source/drain region overlaps the first source/drain region, and wherein the first source/drain region and the second source/drain region have opposite conductivity types.

In an embodiment, the dipole dopant is an n-type dopant selected from the group consisting of Sr, Y, Er, Sc, Mg, and combinations thereof. In an embodiment, the structure further comprises a common gate electrode continuously extending from a first level lower than the first channel region to a second level higher than the second channel region, wherein the common gate electrode forms a first transistor and a second transistor with the first source/drain region and the second source/drain region, respectively. In an embodiment, the high-k dielectric material comprises hafnium oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first semiconductor channel region and a second semiconductor channel region, wherein the second semiconductor channel region overlaps the first semiconductor channel region;
forming a first gate dielectric on the first semiconductor channel region;
forming a second gate dielectric on the second semiconductor channel region;
incorporating a dipole dopant into a first one of the first gate dielectric and the second gate dielectric to a higher atomic percentage, wherein a second one of the first gate dielectric and the second gate dielectric has a lower atomic percentage of the dipole dopant; and
forming a gate electrode on both of the first gate dielectric and the second gate dielectric, wherein the gate electrode and the first gate dielectric form parts of a first transistor, and the gate electrode and the second gate dielectric form parts of a second transistor.

2. The method of claim 1, wherein the incorporating the dipole dopant comprises:
depositing a dipole film on the first gate dielectric and the second gate dielectric;
removing the dipole film from the second gate dielectric;
driving the dipole dopant into the first gate dielectric; and
removing the dipole film.

3. The method of claim 1, wherein the incorporating the dipole dopant is in-situ performed when the first gate dielectric and the second gate dielectric are deposited.

4. The method of claim 1, wherein the first one is deposited as having the lower atomic percentage of the dipole dopant, and the method further comprises replacing the second gate dielectric with another gate dielectric having the higher atomic percentage of the dipole dopant.

5. The method of claim 1, wherein when the first one is deposited as having the higher atomic percentage of the dipole dopant, and the method further comprises replacing the second gate dielectric with another gate dielectric having the lower atomic percentage of the dipole dopant.

6. The method of claim 1, wherein the gate electrode comprises a p-type metal, and wherein the dipole dopant is an n-type dipole dopant.

7. The method of claim 1, wherein the gate electrode comprises an n-type metal, and wherein the dipole dopant is a p-type dipole dopant.

8. The method of claim 1, wherein the first transistor is an n-type transistor, and the second transistor is a p-type transistor.

9. The method of claim 1, wherein the dipole dopant is an n-type dopant selected from the group consisting of La, Sr, Y, Er, Sc, Mg, and combinations thereof.

10. The method of claim 1, wherein the dipole dopant is a p-type dopant selected from the group consisting of Al, Zn, Ga, and combinations thereof.

11. A structure comprising:
a lower transistor comprising:
a first channel region;
a first gate dielectric on the first channel region, wherein the first gate dielectric has a first atomic percentage of a dipole dopant; and
a first gate electrode on the first gate dielectric; and
an upper transistor, wherein a first transistor of the lower transistor and the upper transistor is an n-type transistor, and wherein a second transistor of the lower transistor and the upper transistor is a p-type transistor, and wherein the upper transistor comprises:
a second channel region overlapping the first channel region;
a second gate dielectric on the second channel region, wherein the second gate dielectric has a second atomic percentage of the dipole dopant, and wherein the second atomic percentage is different from the first atomic percentage; and
a second gate electrode on the second gate dielectric, wherein the first gate electrode and the second gate electrode are parts of a same continuous gate electrode.

12. The structure of claim 11, wherein the first transistor is the n-type transistor, and the second transistor is the p-type transistor.

13. The structure of claim 11, wherein the dipole dopant is an n-type dopant selected from the group consisting of La, Sr, Y, Er, Sc, Mg, and combinations thereof.

14. The structure of claim 11, wherein the dipole dopant is a p-type dopant selected from the group consisting of Al, Zn, Ga, and combinations thereof.

15. The structure of claim 11, wherein the first gate dielectric and the second gate dielectric comprise same high-k dielectric materials.

16. The structure of claim 11, wherein the first gate dielectric and the second gate dielectric comprise different high-k dielectric materials.

17. A structure comprising:
a lower transistor comprising:
a first channel region;
a first gate dielectric on the first channel region, wherein the first gate dielectric comprises a high-k dielectric material; and
a first source/drain region connecting to the first channel region; and
an upper transistor comprising:
a second channel region overlapping the first channel region;
a second gate dielectric on the second channel region, wherein the second gate dielectric comprises the high-k dielectric material and a dipole dopant, wherein a first atomic percentage of the dipole dopant in the first gate dielectric is lower than a second atomic percentage of the dipole dopant in the second gate dielectric; and
a second source/drain region connecting to the second channel region, wherein the second source/drain region overlaps the first source/drain region, and wherein the first source/drain region and the second source/drain region have opposite conductivity types.

18. The structure of claim 17, wherein the dipole dopant is an n-type dopant selected from the group consisting of Sr, Y, Er, Sc, Mg, and combinations thereof.

19. The structure of claim 17 further comprising:
a common gate electrode continuously extending from a first level lower than the first channel region to a second level higher than the second channel region, wherein the common gate electrode forms a first transistor and a second transistor with the first source/drain region and the second source/drain region, respectively.

20. The structure of claim 17, wherein the high-k dielectric material comprises hafnium oxide.
